(19) United States
(12) Patent Application Publication
(10) Pub. No.: US 2024/0120958 A1
(43) Pub. Date: Apr. 11, 2024

(54) BLOCKER SIGNAL REMOVAL DEVICE, RECEIVER INPUT UNIT AND/OR WIRELESS COMMUNICATION DEVICE INCLUDING THE SAME, AND METHOD OF USING THE SAME

(71) Applicant: DB HiTek Co., Ltd., Bucheon-si (KR)

(72) Inventor: Ja Geon KOO, Eumseong-gun (KR)

(21) Appl. No.: 18/186,728

(22) Filed: Mar. 20, 2023

(30) Foreign Application Priority Data
Oct. 6, 2022 (KR) 10-2022-0127496

(51) Int. Cl. H04B 1/10

(52) U.S. Cl. CPC H04B 1/1027; H04B 1/1018

(57) ABSTRACT

A blocker signal removal device suitable for a receiver input unit, and a method of using the same are proposed. The blocker signal removal device effectively removes blocker signals in reception signals for the receiver. The blocker signal removal device includes a balun low-noise amplifier having a single input and differential output and a filter circuit coupled to the balun low-noise amplifier and configured to remove only an in-band signal of the reception signals. According to such a configuration, signals of the balun low-noise amplifier and signals of the filter circuit cancel out each other, so that unwanted out-of-band signals are removed from the reception signals, and only the in-band signal remains.

### CROSS REFERENCE TO RELATED APPLICATION

The present application claims priority to Korean Patent Application No. 10-2022-0127496, filed Oct. 6, 2022, the entire contents of which are incorporated herein for all purposes by this reference.

### BACKGROUND OF THE INVENTION

### Field of the Invention

The present disclosure relates to a blocker signal removal device and a method of using the same, wherein the blocker signal removal device comprises a band reject filter (BRF) and a balun low-noise amplifier circuit to effectively remove blocker signals from RF signals received by a receiver input unit including the blocker signal removal device.

### Description of the Related Art

Amplifiers are commonly used in various electronic devices to provide signal amplification. Different types of amplifiers are available for different uses. For example, a wireless communication device such as a cellular phone may include a transmitter and a receiver for two-way communication. In this case, the receiver may also use a low noise amplifier (LNA). The low noise amplifier provides a function of filtering along with noise suppression by resonance of an inductor and a capacitor at a load.

The low noise amplifier may receive signals, which may include components having “target” frequencies and components having “blocker” frequencies. As an example, wireless telephones may process signals received at 1.8 GHz (e.g., a target frequency).

However, the low noise amplifier in the receiver input unit may receive signals of different frequencies (e.g., blocker frequencies). When receiving RF communication signals, the low noise amplifier may receive blocker signals in the vicinity of the RF communication signals, and the blocker signals may interfere with the RF communication signals.

Thus, blocker signals may desensitize low noise amplifiers (LNAs) of receivers in wideband reception applications, thereby degrading the performance of the receivers.

### Documents of Related Art

Korean Patent No. 10-2095867 (Mar. 26, 2020).

### SUMMARY OF THE INVENTION

The present disclosure has been devised to solve the above problem(s), and an objective of the present disclosure is to provide a blocker signal removal device and/or a receiver input unit including the same, and a blocker signal removal method using the blocker signal removal device, wherein the blocker signal removal device includes a circuit comprising a balun low-noise amplifier coupled with a BRF filter, so as to remove blocker signals (e.g., received by the receiver input unit).

The technical problems of the present disclosure are not limited to the above-mentioned technical problems, and other technical problems not described above will be clearly understood by those skilled in the art from the description of the claims.

According to an exemplary embodiment of the present disclosure for achieving the above objective, there is provided a blocker signal removal device, including a balun low-noise amplifier having a single input and a differential output; and a filter circuit coupled to the balun low-noise amplifier and configured to remove only an in-band signal of a plurality of reception signals, wherein the blocker signal removal device is configured to output substantially only the in-band signal on the differential output according to an operation with the filter circuit.

The filter circuit may comprise a band reject filter (BRF).

The balun low-noise amplifier may include a first cascade amplifier including a first common source transistor and a first common gate transistor; and a second cascade amplifier including a second common source transistor and a second common gate transistor.

The first common source transistor may reverse phases of the plurality of reception signals and amplify the plurality of reception signals by a predetermined level, the first common gate transistor may amplify the plurality of reception signals passing through the first common source transistor by a predetermined level, the second common source transistor may reverse phases of the plurality of reception signals passing through the first common source transistor and amplify the plurality of reception signals by a predetermined level, and the second common gate transistor may amplify the plurality of reception signals passing through the second common source transistor by a predetermined level.

The first common gate transistor and the second common gate transistor may have identical amplification magnitudes.

The first common source transistor to the second common gate transistor may comprise MOSFET elements.

The first common source transistor common source transistor may receive a first bias voltage at a gate thereof, a gate of the second common source transistor may receive a second bias voltage, and a common gate of the first common gate transistor and the second common gate transistor may receive a third bias voltage.

The band reject filter may include a first switching unit having an even number of switches that receive the plurality of reception signals from an input terminal; and a second switching unit at an output of each of the switches of the first switching unit, wherein the switches may receive master local oscillator (MLO) signals, and the second switching unit may receive local oscillator (LO) signals.

The second switching unit may comprise respective pairs of switches.

The respective pairs of switches may each comprise a first switch connected to a first node, and a second switch connected to a second node.

According to another exemplary embodiment of the present disclosure, there is provided a wireless communication device including the present blocker signal removal device.

According to a yet another exemplary embodiment of the present disclosure, there is provided a blocker signal removal device, including a balun low-noise amplifier and a band reject filter (BRF), which may be combined with each other, wherein first signals output from the balun low-noise amplifier and second signals output from the band-stop filter may cancel out each other to remove blocker signals and output only an in-band signal.

The balun low-noise amplifier may comprise an amplifier having a single input and differential output.

The band reject filter (BRF) may include a first switching unit having a first plurality of switches receiving master local oscillator (MLO) signals; and a second switching unit having a second plurality of switches, which may be in a pair of parallel structures, connected to outputs of the first plurality of switches, and receiving local oscillator (LO) signals. The blocker signal removal device may further comprise signal processing paths corresponding to the first plurality of switches, and only one of the signal processing paths may be activated at a time to filter the plurality of reception signals.

According to a still another exemplary embodiment of the present disclosure, a method of removing blocker signals comprises receiving RF signals in an amplifier having a single input and differential output; removing only an in-band signal in the RF signals using a filter circuit; and outputting only the in-band signal (e.g., by canceling out remaining ones of the RF signals using filtered signals from the filter circuit).

The filter circuit may comprise a band reject filter (BRF) including a first switching unit having a plurality of first switches receiving master local oscillator (MLO) signals; and a second switching unit having a plurality of second switches (which may be in a pair of parallel structures) connected to outputs of the respective plurality of first switches and receiving local oscillator (LO) signals, wherein only one of a plurality of signal processing paths may be activated and/or operated at a time.

The filter circuit may perform a high pass filter operation on the RF signals and a band reject filter operation to remove signals of a predetermined frequency band in an RF band.

Outputting only the in-band signal may comprise removing out-of-band signals by mixing or combining (i) the RF signals including the in-band signal and the out-of-band signals and (ii) the filtered signals including only the out-of-band signals.

According to the present disclosure as described above, there is provided an effect that unwanted blocker signals in reception signals may be effectively removed with a structure in which the N-path BRF is combined with the balun low-noise amplifier having a single input and a differential output.

Accordingly, the second-order intercept point (IIP2), a linearity index of the receiver, is improved, and overall performance of the receiver may be improved.

### BRIEF DESCRIPTION OF THE DRAWINGS

FIG. 1 is a schematic configuration diagram illustrating a blocker signal removal device according to an exemplary embodiment of the present disclosure.

FIG. 2 is a configuration diagram illustrating a detailed circuit suitable for the blocker signal removal device of FIG. 1.

FIG. 3 illustrates a filtering process in which out-of-band signals are removed from reception signals and only a desired in-band signal is output.

FIGS. 4A and 4B are graphs illustrating results simulations comparing a general low noise amplifier and a low noise amplifier combined with an N-path BRF as disclosed in the present disclosure.

### DETAILED DESCRIPTION OF THE INVENTION

In the present disclosure, various transformations may be applied and various exemplary embodiments may be provided, so specific exemplary embodiments will be illustrated in the drawings and described in detail. However, this is not intended to be limiting to any particular embodiment of the present disclosure.

On the contrary, the present disclosure is to be understood to include all transformations, equivalents, and substitutions that may be included within the idea(s) and the technical scope of the present disclosure. In the following description of the present disclosure, detailed descriptions of known functions and components herein will be omitted when the detailed descriptions may make the subject matter of the present disclosure unclear.

Therefore, the idea(s) of the present disclosure should not be limited to the described exemplary embodiments, and all things equal or equivalent to the claims as well as the claims to be described later fall within the scope of the idea(s) of the present disclosure.

Hereinafter, the present disclosure will be described in more detail based on the exemplary embodiments shown in the drawings.

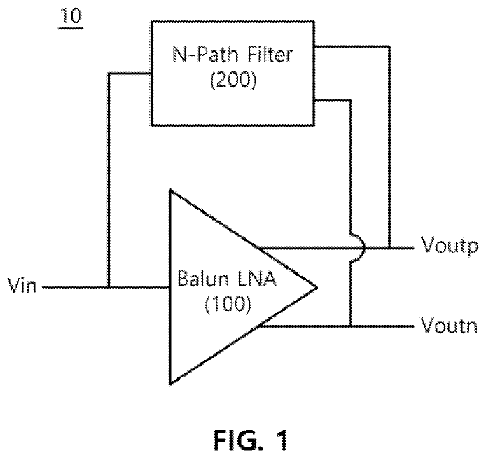

FIG. 1 is a schematic configuration diagram illustrating a blocker signal removal device according to an exemplary embodiment of the present disclosure.

As shown in FIG. 1, the blocker signal removal device 10 of the present disclosure has a configuration in which a balun low-noise amplifier 100 and a filter circuit 200 are combined with each other.

The balun low-noise amplifier (LNA) 100 has a single input V_{IN} and a differential output V_{OUTP}/V_{OUTN}. In the balun LNA 100, the balun converts a single-sided or single pole signal input from an antenna into a differential signal, to be input to an amplifier (e.g., a differential amplifier). In addition, the balun LNA 100 protects the downstream circuitry from electrostatic discharge (ESD) coming through the antenna and helps with input matching. Accordingly, the balun is very important in a low noise amplifier, and benefits from a high quality factor and a structure capable of generating reversed phases of the differential signal (e.g., considering line widths, line spacings, the number of windings, the layout symmetry, etc.).

Efforts are continuously made to optimally design balun LNAs according to such demands. Nonetheless, the efforts still fail to solve problems resulting from receiving unwanted blocker signals in a receiver input unit when conforming to the balun LNA structure.

The filter circuit (e.g., an N-path filter) 200 is an element that removes the above-described blocker signals and is connected to the one input terminal and the differential output in parallel with the balun LNA 100. In the exemplary embodiment, the filter circuit 200 may comprise a band reject filter (BRF). The BRF may have a center frequency that is the same as a center frequency of a channel being used (e.g., of a channel in the receiver), and a bandwidth that is the same as a bandwidth of the channel (e.g., in the receiver). In addition, the blocker signal removal device should include as many BRFs as the number of channels being used (e.g., in the receiver), so in one exemplary embodiment, the BRF may be referred to and described as an N-path BRF (or the N-path filter) 200.

As in the present exemplary embodiment, when the balun LNA 100 and the N-path BRF 200 are combined with each other to form the blocker signal removal device 10, blocker signals may be effectively removed in a receiver input unit including the blocker signal removal device 10, thereby ensuring that the receiver including the receiver input unit has efficient performance.

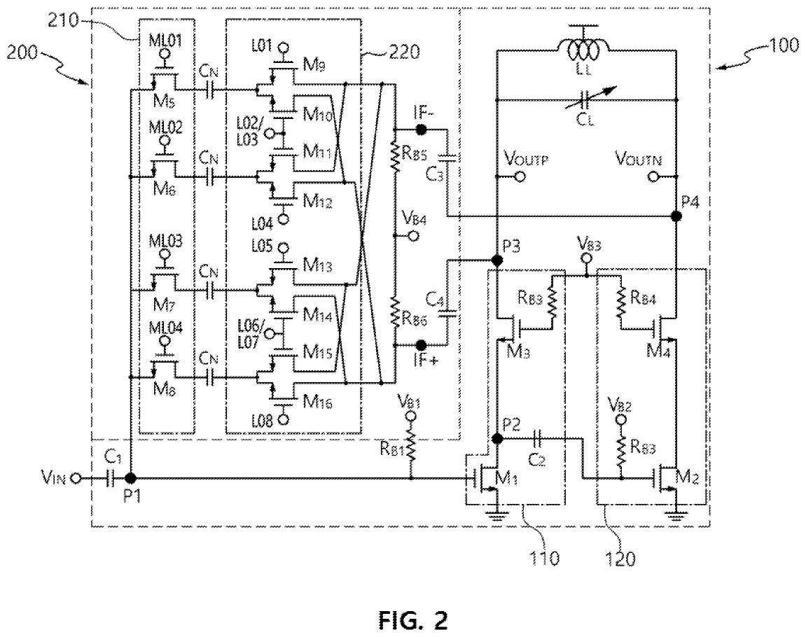

FIG. 2 is a configuration or circuit diagram illustrating a detailed circuit suitable for the blocker signal removal device 10 in FIG. 1, including the balun LNA 100 and the N-path BRF 200.

In FIG. 2, the low noise amplifier 100 may comprise a differential cascade amplifier having a common source and a common gate coupled to each other. That is, the low noise amplifier 100 is configured to include a first cascade amplifier including a common source transistor M1 (i.e., a first transistor) and a common gate transistor M3 (i.e., a third transistor); and a second cascade amplifier including a common source transistor M2 (i.e., a second transistor) and a common gate transistor M4 (i.e., a fourth transistor). Here, a drain of the first transistor M1 and a source of the third transistor M3 are connected to each other, and a drain of the second transistor M2 and a source of the fourth transistor M4 are connected to each other.

The first to fourth transistors M1, M2, M3, and M4 are preferably MOSFET elements (e.g., MOS transistors). However, each of the first to fourth transistors M1, M2, M3, and M4 may comprise another type of transistor (e.g., a bipolar junction transistor). In addition, in one exemplary embodiment, the first to fourth transistors M1, M2, M3, and M4 are N-type transistors (e.g., NMOS transistors), but may also be P-type transistors (e.g., PMOS transistors).

In the first cascade amplifier 110, a gate of the first transistor M1 receives input signals through an input terminal V_{IN}, and the third transistor M3 may improve a frequency response of the first cascade amplifier 110. The reception signals passing through the first cascade amplifier 110 may be output through an output terminal V_{OUTP}.

In the second cascade amplifier 120, a gate of the second transistor M2 may receive the input signals indirectly from the input terminal V_{IN} (e.g., through the node P2 and the capacitor C₂), and the fourth transistor M4 may improve a frequency response of the second cascade amplifier 120. The reception signals passing through the second cascade amplifier 120 may be output through an output terminal V_{OUTN} and, together with the signals on the output terminal V_{OUTP}, form a differential output signal.

As such, each of the first transistor M1 and the second transistor M2 is configured as a common source amplifier so as to convert the single input signal into a differential output signal. In addition, the differential output signal is transmitted on the differential output terminal V_{OUTP}/V_{OUTN} through the third transistor M3 and the fourth transistor M4, and the third transistor M3 and the fourth transistor M4 may increase the impedance at the differential output terminal V_{OUTP}/V_{OUTN}, thereby improving isolation.

An inductor L_{L}, as a load of the low noise amplifier 100, is connected to the differential output terminal V_{OUTP}/V_{OUTN}, and a variable capacitor C_{L} is connected in parallel to the inductor L_{L}. At the differential output terminal V_{OUTP}/V_{OUTN}, the LC resonance of the inductor L_{L} and the variable capacitor C_{L} may provide an impedance matching function.

The first transistor M1, the second transistor M2, the third transistor M3, and the fourth transistor M4 may receive a bias voltage applied to the respective gate terminals thereof. Specifically, a first bias voltage V_{B1} is applied to the gate of the first transistor M1, a second bias voltage V_{B2} is applied to the gate of the second transistor M2, and a third bias voltage V_{B3} is applied to node electrically connected to gates of the third transistor M3 and the fourth transistor M4. Thus, the third transistor M3 and the fourth transistor M4 may have a common gate, and be referred to as “common gate transistors.”

In FIG. 2, the N-path BRF 200 is connected to the input terminal V_{IN} and the differential output terminal V_{OUTP}/V_{OUTN}.

The N-path BRF 200 includes a first switching unit 210 having an even number of switches M5, M6, M7, and M8, which receive the reception signals from the input terminal V_{IN}; and a second switching unit 220 comprising multiple (e.g., a pair of) parallel structures at outputs of the switches M5, M6, M7, and M8 in the first switching unit 210. The second switching unit 220 comprises respective pairs of switches (M9, M10), (M11, M12), (M13, M14), and (M15, M16), and inputs thereof are connected in parallel to respective outputs of the switches M5, M6, M7, and M8. In addition, the outputs of the second switching unit 220 are connected to the differential output terminal V_{OUTP}/V_{OUTN} through a predetermined wiring structure.

The MLO switches M5, M6, M7, and M8 of the first switching unit 210 receive and/or are controlled by master local oscillator (MLO) signals MLO1-MLO4. The switches M₉-M₁₆ of the second switching unit 220 receive and/or are controlled by local oscillator (LO) signals LO1-LO8. In addition, the MLO signals are aligned and/or centered on respective middle parts (or frequencies) of the LO signals.

The connection structure of the first switching unit 210 and the second switching unit 220 in the N-path BRF 200 is as follows.

A signal input through the first switch M5 under the control of an MLO signal MLO1 is output as an intermediate frequency signal through the first pair of switches M9 and M10 in the second switching unit 220. In addition, the switch M9 is connected to a first intermediate frequency node IF−, and the switch M10 is connected to a second intermediate frequency node IF+. Accordingly, the signal may be output from the first pair of switches M9 and M10 by alternatively connecting the switch M9 to the second intermediate frequency node IF+ and the switch M10 to the first intermediate frequency node IF−.

A signal input through the second switch M6 under the control of a second MLO signal MLO2 is output as an intermediate frequency signal through the second pair of switches M11 and M12 in the second switching unit 220. In addition, the switch M11 is connected to the first intermediate frequency node IF−, and the switch M12 is connected to the second intermediate frequency node IF+. Accordingly, the signal may be output from the second pair of switches M11 and M12 by alternatively connecting the switch M11 to the second intermediate frequency node IF+ and the switch M10 to the first intermediate frequency node IF−.

A signal input through the third switch M7 under the control of an MLO signal MLO3 is output as an intermediate frequency signal through the third pair of switches M13 and M14 in the second switching unit 220. In addition, the switch M13 is connected to the first intermediate frequency node IF−, and the sixth LO switch M14 is connected to the second intermediate frequency node IF+. Accordingly, the signal may be output from the third pair of switches M13 and M14 by alternatively connecting the switch M13 to the second intermediate frequency node IF+ and the switch M14 to the first intermediate frequency node IF−.

A signal input through the fourth switch M8 under the control of an MLO signal MLO4 is output as an intermediate frequency signal through the fourth pair of switches M15 and M16 in the second switching unit 220. In addition, the seventh LO switch M15 is connected to the first intermediate frequency node IF−, and the eighth LO switch M16 is connected to the second intermediate frequency node IF+. Accordingly, the signal may be output from the fourth pair of switches M15 and M16 by alternatively connecting the switch M15 to the second intermediate frequency node IF+ and the switch M16 to the first intermediate frequency node IF−.

In FIG. 2, the N-path BRF 200 is designed so that the MLO signals MLO1 to MLO4 do not turn on the switches M5-M8 during times that overlap another MLO signal, and thus the N-path BRF 200 performs a high-pass filter operation in which only one path is activated at a time. The filtered signals (e.g., output on the first and second intermediate frequency nodes IF− and IF+) may be converted again, and thus the N-path BRF 200 may perform a band reject filter operation in a RF band.

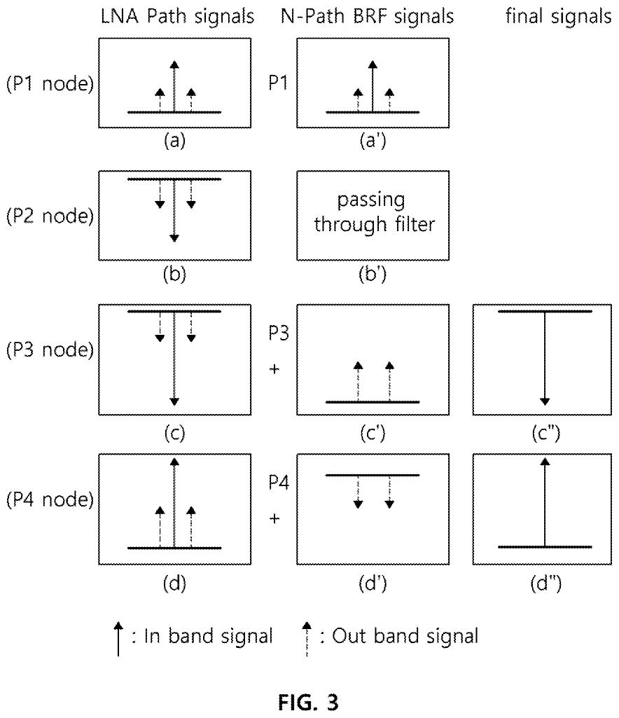

Next, the operation of the blocker signal removal device configured as described above will be described with reference to FIG. 3. FIG. 3 illustrates the filtering process, in which out-of-band signals are removed from reception signals, and only a desired in-band signal is output.

The first cascade amplifier 110 and the second cascade amplifier 120 are separately described.

First, signal processing in the first cascade amplifier 110 and the N-path BRF 200 is described.

When RF signals are received from an antenna and input to the receiver input unit including the blocker signal removal device 100, the reception signals on the P1 node include out-of-band signals as well as an in-band signal (graph (a) in FIG. 3). The exemplary embodiment removes the out-of-band signals in the reception signals.

The reception signals on the P1 node are applied to the first transistor M1 of the first cascade amplifier 110. The reception signals passing through the first transistor M1 are reversed in phase and amplified by a predetermined level, and then output. That is, the first transistor M1 operates as an amplifying transistor that amplifies the reception signals. Accordingly, the signals on the P2 node (i.e., at the drain of the first transistor M1) are shown in graph (b) in FIG. 3. Compared with graph (a) in FIG. 3, the phases are opposite, and the signal is amplified.

The signals on the P2 node pass through the third transistor M3, and the signals on the P3 node at the drain of the third transistor M3 are further amplified and transmitted, while maintaining the phases of the signals on the P2 node. The signals on the P3 node are shown in graph (c) in FIG. 3, and compared with graph (b) in FIG. 3, the signals on the P3 node are more amplified.

In addition, the signals on the P3 node are output through the output terminal V_{OUTP}, and before being output, the signals from the transistor M₃ are combined with the signals output on the node IF+ from the N-path BRF 200. Specifically, the reception signals on the P1 node are also illustrated in graph (a′) in FIG. 3, which are also input to the N-path BRF 200. According to signal processing in the N-path BRF 200, the in-band signal is removed, and only the out-of-band signals pass through. The signals output from the N-path BRF have the form shown in graph (c′) in FIG. 3.

Accordingly, the output signals of the first cascade amplifier 110 (graph (c) in FIG. 3) and the output signals of the N-path BRF 200 (graph (c′) in FIG. 3) include the out-of-band signals having phases opposite to each other and amplitudes that are identical or very similar to each other.

Accordingly, the out-of-band signals on the output terminal V_{OUTP} are cancelled out and effectively removed, and only the in-band signal is output, as shown in graph (c″) in FIG. 3. As such, the out-of-band signals in the reception signals may be removed to provide only the desired in-band signal.

Next, signal processing in the second cascade amplifier 120 and the N-path BRF 200 is described. This signal processing is similar to the signal processing in the first cascade amplifier 110 and the N-path BRF 200 described above, consistent with general principles of differential signal processing.

When the RF signals received from an antenna are input to the receiver input unit, the reception signals on the P1 node include out-of-band signals, as well as an in-band signal (graph (a) in FIG. 3).

The reception signals on the P1 node are applied to the first transistor M1 of the first cascade amplifier 110, and the reception signals passing through the first transistor M1 are reversed in phase and amplified to the predetermined level, and then output.

Accordingly, the reception signals on the P2 node at the drain of the first transistor M1 are shown in graph (b) in FIG. 3. Compared with graph (a), the phases are opposite, and the signals are amplified in graph (b).

The signals on the P2 node are transmitted to the second transistor M2, and when output from the second transistor M2, the signals on the P2 node are reversed in phase again and amplified (e.g., relative to the reception signals on the P1 node). In addition, when passing through the fourth transistor M4, the signals are amplified, but the phases are maintained, so the signals on the P4 node at the drain of the fourth transistor M4 are as shown in graph (d) in FIG. 3. Compared with the initially applied signals in graph (a), both the in-band signal and the out-of-band signals are included and amplified in graph (d).

In addition, the signals on the P4 node are output through the output terminal V_{OUTN}, and before being output, the signals from the transistor M₄ are combined with the output signals on the node IF− from the N-path BRF 200. Specifically, the reception signals on the P1 node are also illustrated in graph (a′) in FIG. 3, which are also input to the N-path BRF 200. According to signal processing in the N-path BRF 200, the in-band signal is removed, and only out-of-band signals pass through. The signals output from the N-path BRF 200 have the form of shown in graph (d′) in FIG. 3.

Accordingly, the output signals of the second cascade amplifier 120 (graph (d) in FIG. 3) and the output signals of the N-path BRF 200 (graph (d′) in FIG. 3) include the out-of-band signals having phases opposite to each other and amplitudes that are identical or very similar to each other.

Accordingly, the out-of-band signals on the output terminal V_{OUTN} are effectively removed, and only the in-band signal is output, as shown in graph (d″) in FIG. 3. As such, the out-of-band signals in the reception signals may be removed to provide only the desired in-band signal.

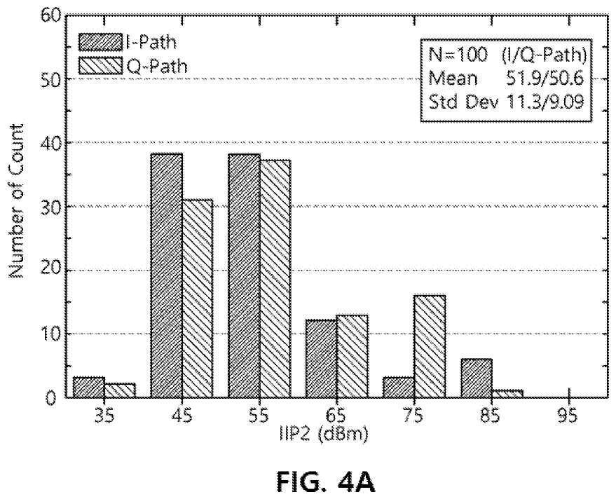

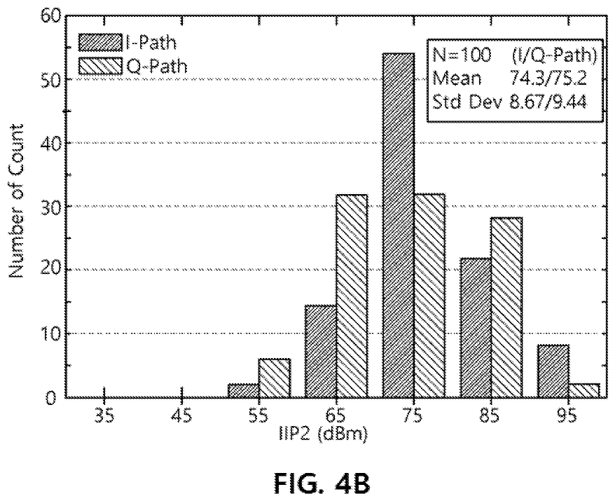

FIGS. 4A and 4B are graphs illustrating results of simulations comparing a general low noise amplifier and the low noise amplifier combined with the N-path BRF as disclosed in the present disclosure. A Monte Carlo simulation was performed to determine IIP2 in each circuit, using 100 random mismatch and process variations, and two-tone test conditions were fLO=1.96 GHz, f1=1.88 GHz, f2=1.881 GHz, and p1=p2=−28 dBm.

FIG. 4A is a graph plotting the simulation results for the general balun low-noise amplifier, and FIG. 4B is a graph plotting the simulation results for the blocker signal removal device of the present disclosure. Referring to these graphs, in FIG. 4A, a performance of about 51.9 dBm/50.6 dBm may be confirmed in I-pass/Q-pass, whereas in FIG. 4B, a performance of about 74.3.9 dBm/75.2.6 dBm may be confirmed in I-pass/Q-pass.

As described above, it may be seen that the present blocker signal removal device provides higher IIP2 performance by about 24 dBm, compared with the conventional low noise amplifier. Thus, the IIP2 (a linearity index of a receiver) is significantly improved by the present blocker signal removal device.

In this way, the present disclosure combines a balun low-noise amplifier with an N-path BRF to remove out-of-band (“blocker”) signals, and through this structure, unwanted blocker signals may be removed in the receiver input unit, thereby improving receiver performance.

As described above, the illustrated exemplary embodiments of the present disclosure have been described, but these are only examples, and it will be apparent to those skilled in the art to which the present disclosure belongs that various modifications, changes, and other equivalent and/or exemplary embodiments are available without departing from the gist and scope of the present disclosure. Therefore, the true technical protection scope of the present disclosure should be determined by the technical idea of the appended claims.

What is claimed is:

1. A blocker signal removal device, comprising:
a balun low-noise amplifier having a single input and a differential output; and
a filter circuit coupled to the balun low-noise amplifier and configured to remove only an in-band signal of a plurality of reception signals,
wherein the balun low-noise amplifier is configured to output substantially only the in-band signal on the differential output according to an operation with the filter circuit.

2. The blocker signal removal device of claim 1, wherein the filter circuit comprises a band reject filter (BRF).

3. The blocker signal removal device of claim 1, wherein the balun low-noise amplifier comprises:
a first cascade amplifier comprising a first common source transistor and a first common gate transistor; and
a second cascade amplifier comprising a second common source transistor and a second common gate transistor.

4. The blocker signal removal device of claim 3, wherein the first common source transistor reverses phases of the plurality of reception signals and amplifies the plurality of reception signals by a predetermined level,
the first common gate transistor amplifies the plurality of reception signals passing through the first common source transistor by a predetermined level,
the second common source transistor reverses phases of the plurality of reception signals passing through the first common source transistor and amplifies the plurality of reception signals by a predetermined level, and
the second common gate transistor amplifies the plurality of reception signals passing through the second common source transistor by a predetermined level.

5. The blocker signal removal device of claim 3, wherein the first common gate transistor and the second common gate transistor have identical amplification magnitudes.

6. The blocker signal removal device of claim 3, wherein the first common source transistor to the second common gate transistor comprise MOSFET elements.

7. The blocker signal removal device of claim 3, wherein the first common source transistor receives a first bias voltage at a gate thereof, a gate of the second common source transistor receives a second bias voltage, and a common gate of the first common gate transistor and the second common gate transistor receive a third bias voltage.

8. The blocker signal removal device of claim 2, wherein the band reject filter comprises:
a first switching unit having an even number of switches that receive the plurality of reception signals from an input terminal; and
a second switching unit at an output of each of the switches of the first switching unit,
the switches receive master local oscillator (MLO) signals, and
the second switching unit receives local oscillator (LO) signals.

9. The blocker signal removal device of claim 8, wherein the second switching unit comprises respective pairs of switches.

10. The blocker signal removal device of claim 9, wherein the respective pairs of switches each comprise a first switch connected to a first node, and
a second switch connected to a second node.

11. A wireless communication device comprising:
the blocker signal removal device of claim 1.

12. A blocker signal removal device, comprising:
a balun low-noise amplifier combined with a band reject filter (BRF),
wherein first signals output from the balun low-noise amplifier and second signals output from the band-stop filter cancel out each other to remove blocker signals and output only an in-band signal.

13. The blocker signal removal device of claim 12, wherein the balun low-noise amplifier comprises an amplifier having a single input and differential output.

14. The blocker signal removal device of claim 12, wherein the band reject filter (BRF) comprises:
a first switching unit having a plurality of first switches receiving master local oscillator (MLO) signals; and
a second switching unit having a second plurality of switches connected to outputs of the respective MLO switches of the first switching unit, and receiving local oscillator (LO) signals.

15. The blocker signal removal device of claim 14, further comprising signal processing paths corresponding to the first plurality of switches, and
only one of the signal processing paths is activated at a time to filter the plurality of reception signals.

16. A method of removing blocker signals, comprising:
receiving RF signals in an amplifier having a single input and differential output;
removing only an in-band signal in the RF signals using a filter circuit; and
outputting only the in-band signal by canceling out remaining ones of the RF signals using filtered signals from the filter circuit.

17. The method of claim 16, wherein the filter circuit comprises a band reject filter (BRF) comprising:
a first switching unit having a plurality of first switches receiving master local oscillator (MLO) signals; and
a second switching unit having a plurality of second switches connected to outputs of the respective plurality of first switches and receiving local oscillator (LO) signals,

18. The method of claim 17, wherein only one of a plurality of signal processing paths is activated and operated at a time.

19. The method of claim 16, wherein the filter circuit performs a high pass filter operation on the RF signals and a band reject filter operation to remove only signals of a predetermined frequency band in an RF band.

20. The method of claim 16, wherein outputting only the in-band signal comprises removing out-of-band signals by mixing or combining (i) the RF signals comprising the in-band signal and the out-of-band signals and (ii) the filtered signals comprising only the out-of-band signals.
